(19) United States
(12) Patent Application Publication
(10) Pub. No.: US 2026/0266659 A1
(43) Pub. Date: Sep. 10, 2026

(54) OPTICAL DETECTOR UNIT, MULTISPECTRAL OPTICAL SENSOR AND METHOD FOR MULTISPECTRAL LIGHT SENSING

(71) Applicant: AMS-OSRAM AG, Premstaetten (AT)

(72) Inventor: Gunter SIESS, Kraftsdorf (DE)

(21) Appl. No.: 19/167,406

(22) PCT Filed: Apr. 12, 2024
(86) PCT No.: PCT/EP2024/059993

§ 371 Date: Sep. 22, 2025

(30) Foreign Application Priority Data
Apr. 28, 2023 (DE) 10 2023 111 163.9

(51) Int. Cl. G01J 3/28; G01J 3/02; H04N 23/71

(52) U.S. Cl. CPC G01J 3/2803; G01J 3/0205; G01J 3/0291; G01J 2003/2813; H04N 23/71

(57) ABSTRACT

An optical detector unit including an optical sensor arranged in a chamber with an aperture in a housing, said optical sensor arranged to detect received photons through the aperture, and a diffuser arranged on top of said aperture on said housing, should provide enhanced accuracy and data reliability. The optical sensor includes an array of sensor pixels of a first type and pixels of a second type, the pixels of the first type each have a different spectral transmission characteristic, each generating a multispectral sensor signal, respectively, and the pixels of the second type have a same transmission characteristic, each generating a compensation sensor signal, and wherein the compensation sensor signals generated by the pixels of the second type are provided for generation of a compensation parameter for each of the sensor pixels.

### CROSS-REFERENCE TO RELATED APPLICATIONS

This application is a national phase of International Application No. PCT/EP2024/059993 filed on Apr. 12, 2024, which claims priority to German patent application DE 10 2023 111 163.9, which was filed on Apr. 28, 2023, the entire contents of both of which are incorporated herein by reference.

### TECHNICAL BACKGROUND OF THE INVENTION

The invention relates to an optical detector unit. The invention more particularly relates to an optical detector unit comprising an optical sensor arranged in a chamber with an aperture in a housing, said optical sensor arranged to detect received photons through the aperture, a diffuser arranged on top of said aperture on said housing, and a measurement unit configured to provide sensor signals generated by the optical sensor. The invention furthermore relates to a multispectral sensor comprising such an optical detector unit, and to a method for multispectral light sensing.

### BACKGROUND

Optical sensors are increasingly being used in such diverse areas of technology as smart phones and mobile devices, smart homes and buildings, industrial automation, medical technology and connected vehicles, etc. At the same time sensor data becomes more complex and is expected to meet the requirements for high accuracy. Further, color and spectral light sensing on a chip-scale have various applications in color identification, data authentication, spectroscopy, and other industrial and consumer-level optical detection applications. In a number of important applications, in particular for camera applications, such sensors are used as ambient light sensors for so-called “auto white balance” functionality, in order to provide essential background information for appropriate correction functionalities and thereby in general improve imaging quality.

Common multispectral sensors are often based on an array of pixels and on-pixel filters for each pixel. For spectroscopic applications the filters can be chosen to have linear independent filter characteristics. In order to accomplish an accurate spectral measurement of a given source, incoming radiation should be known in order to compensate for different response of individual pixels. This way an amplitude of a spectral signal of a pixel can be used to calculate a spectral reconstruction of a light source under study.

However, a homogenous distribution of incoming radiation on the pixel array is an ideal condition. In particular for uses in ambient light sensor devices, homogeneity of incoming light distribution may be of special significance, and in order to provide highly reliable homogenous distribution, diffusors may be used in a position before incoming radiation reaches the pixels in order to mix the incoming light as well as possible and to pass on the light to the sensor array in a homogenous, ideally in a Lambertian, manner. Further, the spectral sensitivity of an interference filter-based multispectral sensor depends strongly on the angular distribution of light hitting the filter on the detector array.

Further, in many existing sensor devices for a mean limit of the field of view (“FOV”) a lid aperture is used in combination with a diffuser on top or, with respect of the direction of incoming light, in front of the aperture in order to collect and mix incoming light from a rather wide incident angle (up to 180°). The position of the lid with respect to the sensor array underneath, however, can vary largely because of tolerances and lack of precision in the packaging during the assembly process. Such variation in relative position may generate variations in amplitude and spectra shape of sensitivity, because of variations in angular power distribution. Depending on the array position, each channel will be affected in a different way. Variations in angular distribution will generate variations in spectra sensitivity.

Depending on the performance of an associated diffuser the system accuracy may also depend on the position of a dominant radiation spot. A wide diffuser object will scatter the light more homogeneous to the inside into the detector array than a dominant and small point. Typically, each diffuser with a common transmittance ratio also has an ideal Lambertian spread and will also vary the power distribution depending on the position (tilt vs. detector) and spectra sensitivity. The knowledge about the setup depending on spectra sensitivity is important to generate a useful transfer matrix for spectral reconstruction.

In order to compensate for these aspects different measurement systems have been proposed. These systems are based on robust optical construction or strictly defined measurement geometries, e.g. measurements under defined angles such as 45°/0° or 22.5°/22.5°, or using an integrating sphere. Such systems are typical for color measurement with strictly fading out of glossy and constant measurement distances. For compensation of non-homogenous radiance distribution by optics, mixing using diffusers and optical lenses is one possibility. However, the field of view, FOV, and size ratio are often not practical. Other solutions employ image analyses using image cameras which may help to get additional information about the characteristic of a measurement surface. In low cost systems additional spacers for touching a surface are often used. But the market is increasingly demanding touchless measurements.

### SUMMARY

The object of the invention is therefore to provide an improved optical detector unit of the type identified above, comprising an optical sensor with an array of detector elements or pixels, that helps overcome the deficiencies identified above. Further, an improved multispectral sensor should be provided, as well as an improved method for multispectral light sensing.

With respect to the optical detector unit, this object is achieved in that:
the optical sensor comprises an array of sensor pixels of a first type and pixels of a second type,
the pixels of the first type each have a different spectral transmission characteristic, each generating a multispectral sensor signal, respectively, and
the pixels of the second type have a same transmission characteristic, each generating a compensation sensor signal,
wherein the compensation sensor signals generated by the pixels of the second type are provided for generation of a compensation parameter for each of the sensor pixels.

Preferred embodiments are subject of the dependent claims.

The invention is based on the consideration that in order to overcome these potential deficiencies and to provide a multispectral sensor with improved performance, the detector unit should be provided with means for compensation of such radiance distribution and for spectral reconstruction. In order to achieve such compensation, the detector unit should be enabled to enable calculation of a compensation parameter for each of the sensor pixels.

In accordance with an aspect of the invention, such enablement may achieved by dividing the sensor pixels of the optical sensor into two subgroups. The pixels of the first subgroup may be used as “conventional” sensor pixels, whereas the pixels of the second subgroup may be designed as compensation pixels, i. e. for compensation purposes. Accordingly, in an embodiment of the invention, the optical sensor may comprise an array of sensor pixels of a first type and pixels of a second type. The pixels of the first type are designed as “conventional” sensor pixels and thus each have a different transmission characteristic. The pixels of the second type, however, may be dedicated to be used to generate compensation sensor signals. These signals then can be processed to calculate a compensation parameter for each of the sensor pixels.

Calculation of said compensation parameters in an aspect of the invention may be executed in an external calculation or computation device. In a preferred embodiment and in accordance with one embodiment of the invention, with a particularly compact and versatile setup, the optical detector unit as such is configured to provide sensor signals in such a “compensated mode”. In this preferred embodiment, the detector unit may comprise an integrated measurement unit arranged to calculate said compensation parameter for each of the sensor pixels and to modify the multispectral sensor signal generated by each of the pixels of the first type by the compensation parameter calculated for the respective pixel in order to obtain a compensated multispectral sensor signal for each pixel of the first type. In yet a further preferred embodiment, this measurement unit arranged to modify the multispectral sensor signal generated by each of the pixels by the compensation parameter calculated for the respective pixel to obtain a compensated multispectral sensor signal for each pixel of the first type.

In a preferred embodiment, the different transmission characteristics of the pixels of the first type are linearly independent. The pixels can be considered channels of the multispectral sensor. Further, in yet another aspect of the invention and in view of the intended application or use of detector unit in an ambient light sensor (ALS), preferably about 5 to 12 channels with different transmission characteristics, in particular peak spectral sensitivity, are provided. In view of this preferred number range for the channels, and taking into account the desired at least approximate reconstruction of the detected spectrum in the visible range, in preferred embodiment the spectral sensitivity of some or each of the channels is of cosine shape, with the Full Width Half Maximum (FWHM) width being approximately equal to the separation between adjacent peaks. In yet another embodiment, the spectral sensitivity of one or each channel may be of Gaussian shape.

According to a preferred aspect of the invention, at least the pixels of the first type each comprise a photodiode and a filter, wherein the filter determines the transmission characteristic of the respective sensor pixel.

According to an aspect of the invention, the compensation pixels, in the sensor array, are positioned such that they allow for the calculation of compensation parameters in a planar extra-/intrapolation. Therefore, in recognition of the fact that a plane is defined by three reference points, in a preferred embodiment, at least three compensation pixels are provided in the sensor array. In the case of incoming irradiation by a radiation source, individual sensor measurement values may be obtained for each of the compensation pixels, and on this basis, by linear extra-/intrapolation in the plane set up by the sensor array, for each sensor pixel an appropriate compensation value may be calculated.

According to yet another aspect of the invention, in order to cover the maximum possible surface between them and to provide maximum difference in measurement values due to geometry parameters such as tilt of the assembly and/or position of the light source, at least some or preferably most of the compensation pixels should be provided as far to the outside of the sensor array as possible. In a preferred embodiment, the compensation pixels therefore are positioned in (outer) corners of the sensor array. In another preferred embodiment, in one aspect of the invention in combination with the corner pixels mentioned above, at least one of the pixels of the second type is located in a centre region of the array of sensor pixels, thereby providing a reference for a pixel in which maximum irradiation is expected under regular conditions.

With respect to the multispectral sensor, the object mentioned above is achieved in that the multispectral sensor comprises an optical detector unit of the type identified above. Further, in a preferred embodiment and in accordance with yet another aspect of the invention, the multispectral sensor is intended for use as an ambient light sensor, in particular for use in camera systems. The multispectral sensor, in various applications, further may comprise an optical emitter unit, which in yet another preferred embodiment comprises an optical emitter may be arranged in a chamber with an aperture in said housing.

With respect to the method for multispectral light sensing, the object identified above in accordance with one aspect of the invention is achieved with the steps of:
detecting received photons by means of an optical sensor arranged in a chamber of a housing through an aperture of said chamber,
wherein the optical sensor comprises an array of sensor pixels of a first type and pixels of a second type,
   for each pixel of the first type generating a multispectral sensor signal,
   for each pixel of the second type generating a compensation sensor signal,
   calculating a compensation parameter for each of the sensor pixels from the compensation sensor signals generated by the pixels of the second type,
   modifying the multispectral sensor signal generated by each of the pixels by the compensation parameter calculated for the respective pixel, and
   providing the modified multispectral sensor signals as output signals of an optical detector unit.

In one aspect the present invention also suggests a camera system, preferably in a smartphone or a wearable device, comprising an ambient light sensor having an optical detector unit of the type identified above.

The major advantages achieved by the invention may be seen in that due to the basic concept of the invention of:
defining corner pixels (no filter) on the multispectral detector array,
using any pixel for different spectral sensitivity (filter), and
supporting a method how to compensate variations in spectral reconstructions,
increased reliability of the sensor output may be achieved.

The suggested use of corner pixels for compensation pixels allows the detection and compensation of geometrical effects that generate variations in spectral reconstruction. This allow also to use bigger single spectral channels with better fill factor or more channels, thereby increasing the performance and accuracy of the detector. In particular, depending on the position of the aperture relative to the position of the array of pixels (package misalignment) and/or the different AOI of an external dominant source, the four corner pixels will get a different signals.

Both the effects of constant offsets (e. g. due to package misalignment) and of dynamic variations (due to e. g. tilt and/or dominant sources) may be detected and compensated. With the parameters, the reconstruction matrix can be spectral compensated. In a preferred embodiment, the geometrical depending change of channel wise spectra sensitivity can be simulated and saved as a calibration data set (e. g. in a look up table).

Further advantages may be seen in that value and direction of package misalignment (pixel wise offset and spectra deformation) may be detected and compensated. It may be distinguished between homogeneous offsets and position depending dynamic effects such as dominant small objects (dynamic variation in specific applications). Yet further, support parameters and methods for spectral compensation at not ideal lambert diffuse light coupling may be provided. Yet further, the sensitivity of detectors may be increased by bigger size of detectors and better fill factors or availability of more different spectral channels because of single spectral channel use.

### BRIEF DESCRIPTION OF THE PREFERRED EMBODIMENTS

Preferred embodiments and aspects of the invention are described further in connection with a drawing. In this drawing,

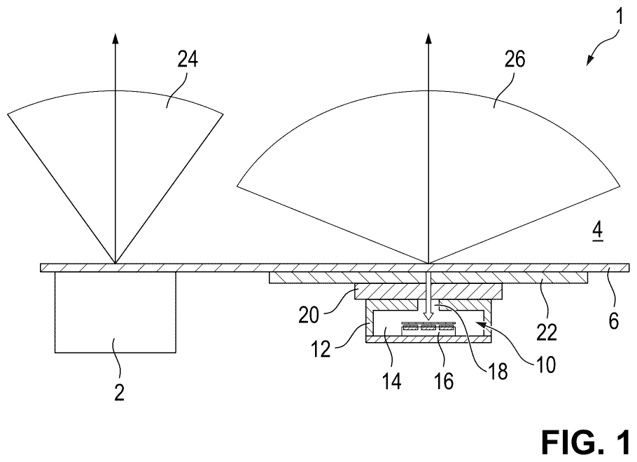

FIG. 1 shows a camera system, in particular for use in a smartphone,

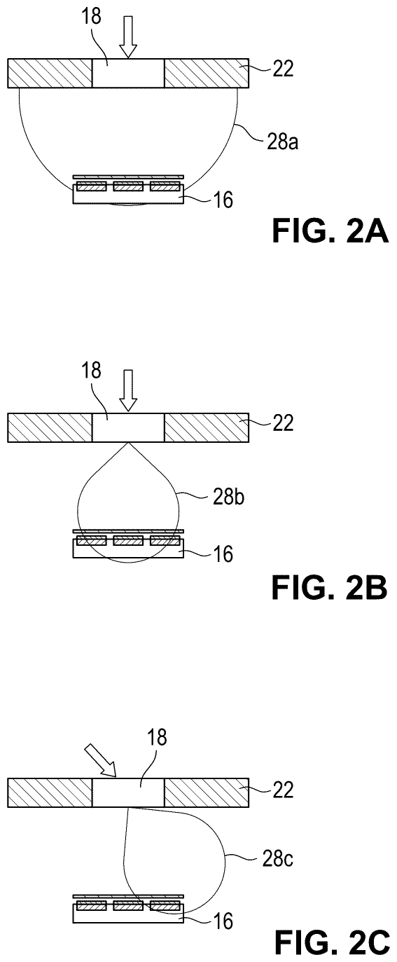

FIGS. 2A-2C schematically show the radiation pattern of various embodiments of diffusers,

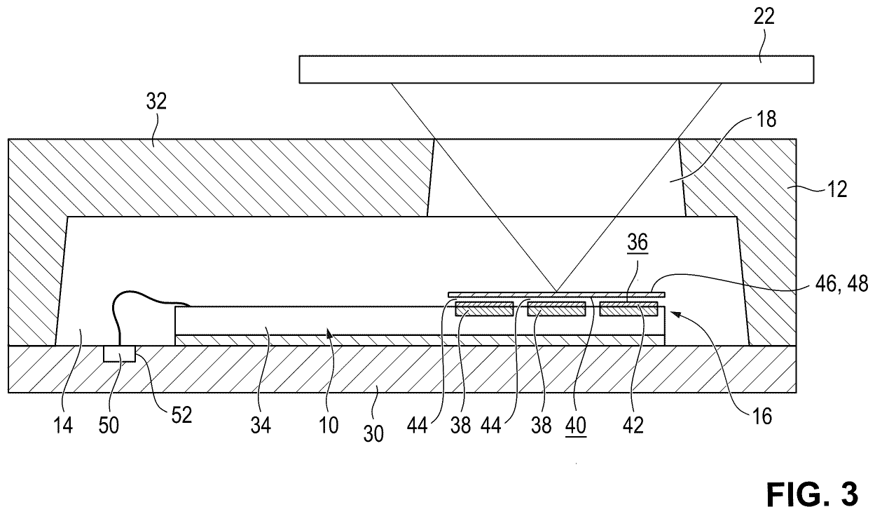

FIG. 3 shows an optical detector unit of the camera system of FIG. 1 in cross section;

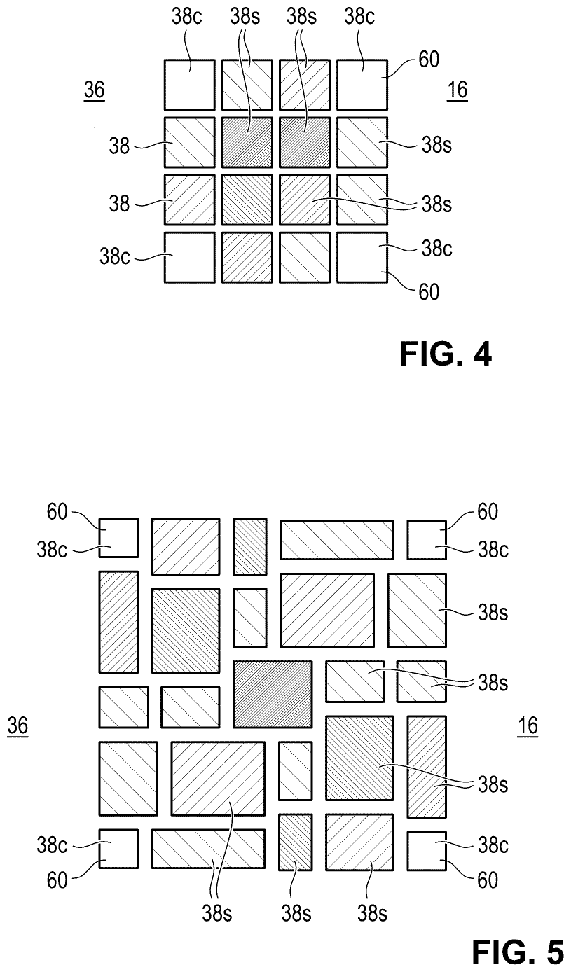

FIGS. 4-6 each show an embodiment of an optical sensor for a multispectral sensor;

Identical parts are labelled by the same reference numerals.

### DETAILED DESCRIPTION OF THE PREFERRED EMBODIMENTS

FIG. 1 shows an example of a camera system 1 in cross section that in the embodiment shown is integrated into a mobile device such as a smartphone. The camera system 1, as its major components, comprises the actual camera sensor system 2, the details of which are of lesser significance for the invention disclosed here, and an ambient light sensor 4 associated therewith. The camera sensor system 2 and the ambient light sensor 4 are mounted at the back of a common cover glass 6, which may be the cover glass 6 of the smartphone as such. The ambient light sensor 4 is used mainly for so-called “auto white balance” functionality in the camera system 1, in order to provide essential background information for appropriate correction functionalities and thereby in general improve imaging quality of the camera system 1.

The ambient light sensor 4 comprises an optical detector unit 10 in the form and design of an optical sensor chip. It is noted that the concept proposed herein can be applied for various types of optical sensor chips and optical devices and that the present invention relates to the design of the optical detector unit 10 alone and therefore, within the scope of the present invention, may very well be used in an optical detector unit 10 in other applications.

The optical detector unit 10 of the ambient sensor 4 comprises a housing 12 with a sensor chamber 14 in which the actual sensor unit 16 is positioned. In order to allow for proper passage of light or radiation to reach the sensor unit 16 through the housing 12, the housing 12 is provided with an opening or aperture 18. The aperture 18 is covered by an infrared cut filter 20, which in turn is covered by a diffuser 22. The diffuser 22 is positioned directly adjacent to the cover glass 6. For sake of illustration, the field of view of the camera detection system 2 and the field of view of the ambient light sensors 4 are also shown in FIG. 1, symbolized as cones 24, 26, respectively.

FIGS. 2A-2C schematically show the radiation patterns of various types and/or situations for the diffuser 22. In an ideal system, as shown in FIG. 2A, the diffuser 22 should completely mix and rescatter light or radiation coming in through the cover glass 6, generating a semi-spherical (resulting in semi-circular shape in cross sectional view) radiation pattern 28a of so-called Lambertian shape. This “ideal” radiation pattern will result in laterally almost homogenous exposure of the sensor unit 16 underneath the diffusor 22. In particular, in such an ideal system the sensor unit 16 would detect and be limited by the aperture 18 behind the diffuser 22. In real systems, however, deviations from such ideal behaviour must be expected, possibly due to imperfections in the diffusor 22 or the surrounding components, or reduced diffusing characteristics in favour of increased transmittance, resulting in a more droplet shaped radiation pattern 28b as shown in FIG. 2B, or possible due to dominant light sources irradiating from a tilt angle resulting in a radiation pattern 28c as shown in FIG. 2C. Obviously, in the latter two cases the impact of the incoming radiation on the sensor unit 16 underneath the diffusor is laterally inhomogeneous.

The optical detector unit 10 of the ambient sensor 4 is shown in enlarged cross-sectional view in FIG. 3. As shown in FIG. 3, the housing 12 of the detector unit 10 is arranged on a substrate or carrier 30. A cover section or lid 32 forming the aperture 18 and also part of the housing 12, is located opposite to the carrier 30 and thereby covers the chamber 14. The carrier or substrate 30 provides mechanical support and electrical connectivity to electronic components which are integrated into the optical detector unit 10. For example, the carrier 30 may comprise a printed circuit board, PCB (not shown). However, in other embodiments (not shown) the carrier 30 can also be part of the housing 12, and electronic components may be embedded into the housing 12 by molding for example.

As part of the optical detector unit 10, the optical sensor unit 16 is arranged inside the chamber 14 and on the carrier 30. In this particular embodiment, the optical sensor 16 is integrated into a single semiconductor sensor die 34 together with other electronics. The optical sensor comprises an array 36 of individual optical detector elements or pixels 38 which will be discussed in further detail below. The pixels 38 may be implemented as photodiodes, for example.

As further part of the optical detector unit 10, an array 40 of optical filters 42 is arranged in the chamber 14 above the optical sensor unit 16. The array 40 of optical filters 42 is attached to the optical sensor 16. The pixels 38 each are associated with an associated optical filter 42 having a different transmission characteristic. Together the pixels 38 and associated filter 42 form a channel 44 of the optical detector unit 10. The optical filters 42 may be interference filters such as an optical cut-off filter, bandpass, long or short pass filter, dielectric filters, Fabry-Perot filters and/or polymer filters.

In order to allow for proper passage of light or radiation, the cover or lid 32 of the housing 12 is provided with the aperture 18. The aperture 18 is positioned above the optical sensor 16. In fact, the aperture 18 lies within a field of view (FOV) of the optical sensor 16. The field of view of the optical sensor 16 includes all points in space from where, at least theoretically, light radiated from an external radiation or light source may traverse towards the optical sensor 16, e.g. for a fixed detector position and orientation.

A control unit 50 and a measurement unit 52 are integrated into the semiconductor sensor die 34 alongside with the optical sensor 16. The measurement unit 52 can be considered a control unit for the optical sensor unit 2. For example, it provides sensor signals which are generated by the optical sensor 16. The control unit 50 and measurement unit 52 may be implemented as control logic, state machines, microprocessor and the like. They may also comprise additional components such as analog-to-digital converters, time-to-digital converters, amplifiers which too are located in the semiconductor sensor die 34. The semiconductor die 34 may have a printed circuit board PCB providing electrical communication to the individual components of the multispectral sensor. In operation, incoming radiation can be detected entering through the aperture 18 by means of the optical sensor 16. Each sensor pixel 38 in reaction generates a multispectral sensor signal, respectively. The measurement unit 52 therefore in total provides a set of multispectral sensor signals.

In general, the accuracy and reliability of the output signals provided by the optical sensor 16 may be limited and lowered by a number of factors. In particular, both static and dynamic sources for potential errors in the signals may be of relevance. As an example of static sources for such errors, geometry factors may become relevant. More precisely, the spectral sensitivity of an interference filter based multispectral sensor as used in the embodiment shown depends strongly on the angular distribution of light hitting the respective filter 42 on the detector array 36. Considering that the FOV of the optical sensor 16 is limited by the aperture 18 in the housing 12, the relative lateral position of the detector array 36 relative to the aperture 38 is importance for accuracy. Ideally, the sensor array 36 ought to be concentric with aperture 38, thereby providing symmetric conditions for all individual pixels 38. The positioning and its precision, however, may vary and be affected by differences or tolerances in the packaging process during assembly of the detector unit 2 and the relative alignment of the components, thereby potentially generating variations in amplitude and spectral shape of sensitivity, because of variations in angular power distribution.

As another source of potential errors or misreadings of the pixels 38, as explained above in the context of FIGS. 2A-2C, dynamic aspects such as tilt or angular displacement of the sensor arrangement relative to the dominant radiation or light source should be considered as well as effects created by the radiation or light source as such. Depending on the performance of an integrated diffuser, the system accuracy in particular is also depending on the position of a dominant radiation spot or light source. A wide diffused object will scatter the light more homogeneously into the inside of the detector array 36 than a dominant and small point-type light source. Typically, each diffuser with a common transmittance ratio has also an ideal Lambertian spread and will also vary the power distribution depending on the position (tilt vs. detector) and spectral sensitivity.

Yet furthermore, the optical filters 42 are characterized by spectral transmission characteristics, respectively. Finally, the channels 44 have a spectral sensitivity of their own, may be prone to crosstalk and typically show temperature dependence. A temperature profile of channels 44 may be affected by ambient temperature, device temperature, emitter temperature and thermal gradients in the optical device. Any of these effects may contribute to errors in the generation of sensor signals.

In order to overcome these potential deficiencies and to provide a multispectral optical detector unit 10 with improved performance, in accordance with an aspect of the present invention, the detector unit 10 in the embodiment shown is provided with means for compensation of such radiance distribution and for spectral reconstruction. In order to achieve such compensation, the detector unit 10 in the embodiment shown is enabled to calculate a compensation parameter for each of the channels 44.

In accordance with one aspect of the invention, such enablement is achieved by providing a subgroup of the sensor pixels 38 of the optical sensor 16, the pixels 38 of said subgroup being designed as compensation pixels 38c. Accordingly, in an embodiment of the invention, the optical sensor 16 comprises an array 36 of sensor pixels 38s of a first type and pixels 38c of a second type. The pixels 38s of the first type are designed as “conventional” sensor pixels 38s and thus each have a different transmission characteristic. The pixels 38c of the second type, however, are either associated with optical filters 42 having have a same transmission characteristic or are associated with no optical filter. In the latter case the properties of the pixel 38c itself determine its transmission characteristic. Each pixel 38c of the second type, denoted compensation pixel hereinafter, generates a compensation sensor signal, respectively, and in total a set of compensation sensor signals is generated. These signals can be processed to calculate a compensation parameter for each of the sensor pixels 38s.

According to an aspect of the invention, the compensation pixels 38c, in the sensor array 36, are positioned such that they allow for the calculation of compensation parameters in a planar extra-/intrapolation. Therefore, in the sensor array 36, at least three compensation pixels 38c are provided, since a plane is defined by three reference points. In the case of incoming irradiation by a radiation source, individual sensor measurement values may be obtained for each of the compensation pixels 38c, and on this basis, by linear extra-/intrapolation in the plane set up by the sensor array 36, for each sensor pixel 38s an appropriate compensation value may be calculated.

In view of the spirit of the present invention, as mentioned above, at least three compensation pixels 38c should be provided. In general, the compensation pixels 38c may be positioned anywhere in the detector array 36. According to yet another aspect of the invention, however, at least some or preferably all compensation pixels 38c should be provided as far to the outside of the sensor array 36 as possible, in particular in order to cover the maximum possible surface between them and to provide maximum difference in measurement values due to geometry parameter such as tilt of the assembly and/or position of the light source. In a preferred embodiment, the compensation pixels 38c are positioned in (outer) corners 60 of the sensor array. In other words: In an aspect of the invention, the corner pixels 38c of the sensor array 36 are designed for the functionality of compensation pixels 38c.

FIG. 4 shows an embodiment of an optical sensor 16 for an optical detector unit 10 in accordance with these considerations. The drawing shows a top-view of the array 36 of pixels 38 which are arranged in an 4×4 configuration. Four compensation pixels 38c are symmetrically distributed over and are located in the corners 60 of the pixel array 36. The remaining pixels 38 are sensor pixels 38s. The arrays 40 of optical filters 42 are not shown in this representation but are aligned with the pixels 38s in the pixel array 36. For example, the optical filters 42 are implemented as interference filters.

In the embodiment shown in FIG. 4, for each channel 44 shown, identical geometries for the pixels 38 are provided, each being of square shape. In an alternative embodiment as shown in FIG. 5 in top view, various shapes and sizes for the individual channels 44 or pixels 38 may be used. In particular, under the preferred boundary condition that at least a number of three compensation pixels 38c, these distributed in x and y direction of the array 36, should be provided to properly describe geometrical aspects and variations of the array, size, symmetry and number of channels 44 may be freely chosen in the scope of the invention. Further, any combination with state of the art opposite channels 44 of same spectral filter properties may be provided. As mentioned, the corner pixels or the compensation pixels 38c may be free of filter or use specific band pass filters 42.

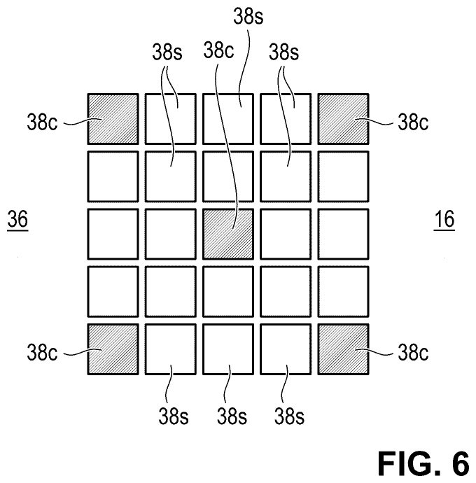

In yet another preferred embodiment, as shown in FIG. 6 in top view, at least one of the pixels 38c of the second type or compensation pixels 38c is located in a centre region 62 of the array 36 of sensor pixels 38. This central compensation pixel 38c may be used to analyse diffuse spread and dominant angle of the irradiating light source.

The transmission characteristics of the sensor pixels 38s in the embodiments shown are linearly independent and may be considered channels 44 of the detector unit 10. With linearly independent transmission characteristics only light of a defined wavelength is attributed to a certain channel 44 or spectral pixel 38s. In the preferred embodiment shown in FIG. 4, the detector unit 10 is intended to be used in the ambient light sensor 4 and accordingly is equipped with 12 sensor pixels 38s, equivalent to 12 sensor channels 44 and thus in the preferred range of about 5 to 12 channels with different transmission characteristics. In the preferred embodiment shown, taking into account the desired at least approximate reconstruction of the detected spectrum in the visible range for providing ambient light information, the spectral sensitivity of the channels 44 is of cosine shape, with the Full Width Half Maximum (FWHM) width being approximately equal to the separation between adjacent peaks. In other embodiments, though, the spectral sensitivity of one or each channel may be of Gaussian shape.

The spectral sensitivity for spectrometric analyses can be achieved by the array 40 of optical filters 42 introduced above, e.g. based on appropriate design of the interference filters. The filters 42 can be arranged so that each sensor pixel 38s has its own spectral sensitivity. By combining the channels 44 appropriately, a spectral response distribution (or spectrum) of the measuring sample characteristics can be created. This can be analysed by algorithmic reconstruction methods.

The concept discussed before allows for a multispectral sensor 1 which can be based on an array 36 of sensor pixels 38s. Each pixel 38s has a known spectral characteristic. All sensor pixels 38s are linear independent, e.g. each sensor pixel 38s is sensitive for a narrow band of light. This can be UV, VIS, NIR and/or IR. Spectral information characteristic of a light source can be reconstructed. The optical sensor 1 can be complemented with optics to determine a field of view (FOV) of the multispectral sensor 1, e.g. for limiting the viewing area on the target. The optics can be a micro-lens array arranged close to the sensor array 36 and/or a separate lens for optical imaging of the target area on the optical sensor. In fact, a position of a sensor pixel 38s can be arranged to detect only from certain ranges on the target.

Compensation pixels 38c can be distributed over the optical sensor 16, e.g. in corners 60 of the array 36 and may define the scope of the viewed target area. Compensation signals generated from these pixels 38c can be used to estimate effects of inhomogeneous radiance. In order to recalculate information of target characteristic or radiance distribution of radiation sources it may be advisable that the compensation pixels 38c have the same spectral sensitivities so that no spectral differences will be interpreted. The compensation pixels 38c can be configured without a filter or with the same filter to improve independence. The filter of the compensation pixels 38c can also be one part of the spectral measurement.

The compensation signals and their deviation can be used as parameters for describing an inhomogeneous radiance incident on the optical sensor 10. By knowing parts of other optical effects it may be possible to generate a model of a radiance gradient to compensate signal amplitudes of each sensor pixel 38s by its position. The result of this compensation may result in a more robust reconstruction of a spectral radiation characteristic.

In general, the compensation may be based upon conventional compensation methods for individual spectral sensitivity of sensors at ideal diffuse illumination conditions. In particular, steps may be chosen as follows:

Initial operation/calibration:
Obtain typical compensation pixel data from ideal diffuse illumination conditions (C_typ). This contains also the information about some package alignments.
   Application, measurement:
Get compensation pixel data at application condition (C_app)
   Application, compensation
Calculate the ratio to typical and scale each to mean C_ratio=(C_app/C/app_mean)/(C_typ/C_typ_mean)
Calculate the pixel related ratio from position interpolation P_ratio=interpolation (C_position, C_ratio, P_position)
Calculate the compensated pixel value P_comp=P_app*P_ratio

A compensation of spectral shift due to angular variation could be done separately based on lookup table or prediction algorithm. At higher effort, a new transfer matrix may be calculated.

The embodiments of the optical sensor device 1 discussed herein have been disclosed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

In particular, the disclosure is not limited to the disclosed embodiments, and gives examples of as many alternatives as possible for the features included in the embodiments discussed. However, it is intended that any modifications, equivalents and substitutions of the disclosed concepts be included within the scope of the claims which are appended hereto.

Features recited in separate dependent claims may be advantageously combined. Moreover, reference signs used in the claims are not limited to be construed as limiting the scope of the claims.

Furthermore, as used herein, the term “comprising” does not exclude other elements. In addition, as used herein, the article “a” is intended to include one or more than one component or element, and is not limited to be construed as meaning only one.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

### List Of Reference Numerals

1 camera system
2 camera detection system
4 ambient light sensor
6 cover glass
10 optical detector unit
12 housing
14 chamber
16 sensor unit
18 aperture
20 IR cut filter
22 diffuser
24, 26 cone
28 radiation pattern
30 substrate
32 lid
34 sensor die
36 array
38 pixel
38c compensation pixel
38s sensor pixel
40 array
42 optical filter
44 channel
50 control unit
52 measurement unit
60 corner
62 centre region

1. An optical detector unit comprising:
an optical sensor arranged in a chamber with an aperture in a housing, said optical sensor arranged to detect received photons through the aperture, and
a diffuser arranged on top of said aperture on said housing;
wherein:
the optical sensor comprises an array of sensor pixels of a first type and pixels of a second type,
the pixels of the first type each have a different spectral transmission characteristic, each generating a multispectral sensor signal, respectively, and
the pixels of the second type have a same transmission characteristic, each generating a compensation sensor signal,
and wherein the compensation sensor signals generated by the pixels of the second type are provided for generation of a compensation parameter for each of the sensor pixels.

2. The optical detector unit of claim 1, further comprising a measurement unit configured to provide sensor signals generated by the optical sensor, wherein said measurement unit is arranged to calculate said compensation parameter for each of the sensor pixels and to modify the multispectral sensor signal generated by each of the pixels of the first type by the compensation parameter calculated for the respective pixel to obtain a compensated multispectral sensor signal for each pixel of the first type.

3. The optical detector unit of claim 1, wherein the different transmission characteristics of the pixels of the first type are linearly independent.

4. The optical detector unit of claim 1, wherein at least the pixels of the first type each comprise a photodiode and a filter, wherein the filter determines the transmission characteristic of the respective sensor pixel.

5. The optical detector unit of claim 1, in which at least three pixels of the second type are provided.

6. The optical detector unit of claim 1, in which at least some the pixels of the second type are located in corners of the array of sensor pixels.

7. The optical detector unit of claim 1, in which at least one of the pixels of the second type is located in a center region of the array of sensor pixels.

8. A multispectral sensor, comprising an optical detector unit of claim 1.

9. The multispectral sensor of claim 8, which is designed as an Ambient Light Sensor.

10. A method for multispectral light sensing, comprising the steps of:
detecting received photons by means of an optical sensor arranged in a chamber of a housing through a diffuser arranged on top of said housing and through an aperture of said chamber,
wherein the optical sensor comprises an array of sensor pixels of a first type and pixels of a second type,
for each pixel of the first type generating a multispectral sensor signal,
for each pixel of the second type generating a compensation sensor signal, and
calculating a compensation parameter for each of the sensor pixels from the compensation sensor signals generated by the pixels of the second type.

11. The method of claim 10, further comprising the steps of:
modifying the multispectral sensor signal generated by each of the pixels by the compensation parameter calculated for the respective pixel, and
providing the modified multispectral sensor signals as output signals of an optical detector unit.

12. The method of claim 10, wherein the method is used in an application for ambient light sensing.

13. A camera system comprising an ambient light sensor having an optical detector unit of claim 1.
